(19) United States
(12) Patent Application Publication
(10) Pub. No.: US 2023/0352628 A1
(43) Pub. Date: Nov. 2, 2023

(54) LIGHT EMITTING DEVICE

(71) Applicant: XIAMEN SAN’AN OPTOELECTRONICS CO., LTD., Xiamen (CN)

(72) Inventors: Bin JIANG, Xiamen (CN); Yashu ZANG, Xiamen (CN); Chung-Ying CHANG, Xiamen (CN); Kang-Wei PENG, Xiamen (CN); Sihe CHEN, Xiamen (CN); Gong CHEN, Xiamen (CN); Weichun TSENG, Xiamen (CN); Ming-Chun TSENG, Xiamen (CN); Siyi LONG, Xiamen (CN)

(21) Appl. No.: 18/137,824

(22) Filed: Apr. 21, 2023

(30) Foreign Application Priority Data
Apr. 29, 2022 (CN) 202210473236.1

(51) Int. Cl. H01L 33/38; H01L 33/62; H01L 25/075; H01L 33/58; H01L 33/26; H01L 33/24; H01L 27/15

(52) U.S. Cl. CPC H01L 33/382; H01L 33/62; H01L 25/0753; H01L 33/58; H01L 33/26; H01L 33/24; H01L 27/156

(57) ABSTRACT

According to the disclosure, the light emitting device includes a substrate, a semiconductor structure, a first electrode unit, a second electrode unit, a plurality of micro elements. The substrate has a first surface and a second surface opposite to the first surface. The semiconductor structure located on top of the first surface of the substrate, and has a first semiconductor layer, an active layer, and a second semiconductor layer that are stacked sequentially. The first electrode unit is electrically connected to the first semiconductor layer. The second electrode unit is electrically connected to the second semiconductor layer. The plurality of micro elements are located on the second surface of the substrate. Each of the micro elements has a base that is protrusion that has a base diameter ranging from 400 nm to 1000 nm.

### CROSS-REFERENCE TO RELATED APPLICATION

This application claims priority to Chinese invention Patent Application No. 202210473236.1, filed on Apr. 29, 2022.

### FIELD

The disclosure relates to a light emitting device, and more particularly to an ultra-violet light emitting device.

### BACKGROUND

Light emitting diodes (LEDs) are semiconductor devices that emit light when supplied with a current. LEDs are usually made from GaN, GaAs, GaP, GaAsP semiconductors, and have an electroluminescent P-N junction at the heart of its operation. When driven by a positive current, electrons in the N region of the LED recombine with electron holes in the P region, thereby emitting light. LEDs have the advantage of high luminance, high efficiency, compact size, and long service life, and are considered the lighting technology with the most future potential.

Ultra-violet (UV) light emitting diodes are LEDs that emit UV light and are widely used in the fields of biomedical technology, fraud detection, purification (air, water), data storage, and military technology etc.

UV LEDs have specific technological hurdles to overcome in comparison to conventional LEDs (e.g., blue light LEDs). For example, most encapsulation materials used for LEDs are susceptible to damage from UV light. Even fluorine resin, which is sometimes used for encapsulating UV LEDs may crack after prolonged exposure to the UV light emitted from UV LEDs. Therefore, UV LEDs are often un-encapsulated so that the UV light directly exits into air. However, this enlarges the angle of total internal reflection of the UV light and hence decreases light extraction efficiency. In addition, since UV light of the UV LED has a shorter wavelength compared to other wavelengths, such as wavelengths of blue light and ret light emitted by LEDs, UV LEDs are more susceptible to the phenomena of total internal reflection than LEDs that emit blue or red light, and may have lower light extraction efficiency.

In summary of the above, an important concern in the current field of LED technology is to find solutions that may increase the light extraction efficiency of LED.

### SUMMARY

Therefore, an object of the disclosure is to provide a light emitting device that can alleviate at least one of the drawbacks of the prior art.

According to the disclosure, the light emitting device includes a substrate, a semiconductor structure, a first electrode unit, a second electrode unit, and a plurality of micro elements. The substrate has a first surface and a second surface opposite to the first surface. The semiconductor structure is located on top of the first surface of the substrate, and has a first semiconductor layer, an active layer, and a second semiconductor layer that are stacked sequentially. The first electrode unit is electrically connected to the first semiconductor layer. The second electrode unit is electrically connected to the second semiconductor layer. The plurality of micro elements are located on the second surface of the substrate. Each of the micro elements is a protrusion that has a base with a base diameter ranging from 400 nm to 1000 nm.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is cross-sectional view illustrating a first embodiment of a light emitting device according to the present disclosure.

FIG. 2 is an enlarged cross-sectional view of an area A in FIG. 1.

FIG. 3 is a schematic view illustrating a second surface of a substrate of the first embodiment.

FIG. 4 is a cross-sectional view illustrating a second embodiment of the light emitting device.

FIG. 5 is a cross-sectional view showing an intermediate step of fabricating the second embodiment.

FIG. 6 is a cross-sectional view illustrating a third embodiment of the light emitting device.

FIG. 7 is a diagram showing results from a third experiment using samples of the first embodiment and the third embodiment of the light emitting device.

FIG. 8 is a cross-sectional view illustrating a fourth embodiment of the light emitting device.

FIG. 9 is a schematic cross sectional view illustrating a stealth dicing process performed on the light emitting device according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

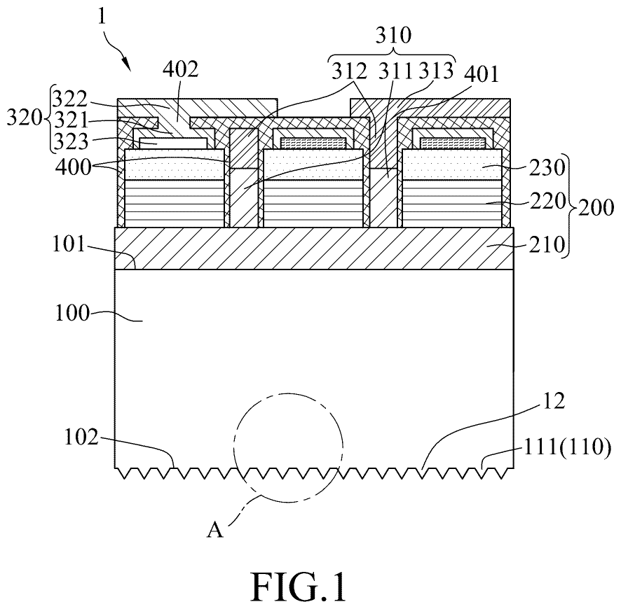

Referring to FIG. 1, a first embodiment of a light emitting device 1 according to the present disclosure is shown. The light emitting device 1 includes a substrate 100, a semiconductor structure 200, a first electrode unit 310, a second electrode unit 320, and a plurality of micro elements 110.

The substrate 100 has a first surface 101 and a second surface 102 opposite to the first surface. In this embodiment, the first surface 101 of the light emitting device 1 is facing upwardly, and the second surface 102 of the light emitting device 1 is facing downwardly. However, this is not a limitation of the disclosure. The substrate 100 may be an insulating substrate. In some embodiments, the substrate 100 may include a transparent insulating material or semi-transparent insulating material. In this embodiment, the substrate 100 includes Al₂O₃; however, in other embodiments, the substrate 100 may include Al₂O₃, GaN, SiC or glass. When the substrate 100 includes a transparent or semi-transparent material, light emitted from the semiconductor structure 200 may pass through the substrate 100 and be emitted from a side of the substrate 100 that faces away from the semiconductor structure 200 (the second surface 102 of the substrate 100). The semiconductor structure 200 includes an active layer 220. The first electrode unit 310 and the second electrode unit 320 are located on a side of the semiconductor structure 200 distal to the second surface 102 of the substrate 100. In this embodiment, light generated in the active layer 220 of the semiconductor structure is emitted along a direction towards the substrate 100. In other words, the light exiting surface of the light emitting device 1 is the side of the substrate 100 that faces away from the semiconductor structure 200, the first electrode unit 310, and the second electrode unit 320.

In some embodiments, the substrate 100 should have a suitable thickness so as to increase the light extraction efficiency of the side of the substrate that faces away from the semiconductor structure 200. The substrate 100 may have a thickness that may range from 200 μm to 900 μm. In some embodiments, the substrate 100 may have a thickness that ranges from 250 μm to 400 μm, in other embodiments, the thickness may range from 400 μm to 550 μm, or in still other embodiments from 550 μm to 750 μm.

Referring to FIG. 1, the semiconductor structure 200 is located on top of the first surface 101 of the substrate 100, and has a first semiconductor layer 210, the active layer 220, and a second semiconductor layer 230 that are stacked sequentially. The first semiconductor layer 210 is formed on the first surface 101 of the substrate 100 and may be an N-type semiconductor layer that provides electrons to the active layer 220. In some embodiments, the first semiconductor layer 210 is a nitride-based compound doped with an N-type dopant. The nitride-based compound may be doped with one or multiple N-type dopants belonging to Group 4 elements of the periodic table. The N-type dopant may be Si, Ge, Sn or any combination of the above. In some embodiments, a buffer layer may be formed between the first semiconductor layer 210 and the substrate 100 to reduce lattice mismatch. The buffer layer may include an unintentionally doped GaN layer (u-GaN), or an unintentionally doped AlGaN layer (u-AlGaN). In some embodiments, the first semiconductor layer 210 may be connected with the substrate 100 through an adhesion layer.

The active layer 220 is formed on top of the first semiconductor layer 210 and may have a quantum well (QW) structure. In some embodiments, the active layer 220 may be a multiple quantum well (MQW) structure with alternatingly arranged layers of wells and barriers. For example, in some embodiments, the active layer 220 may be a GaN/AlGaN, an InAlGaN/InAlGaN, or an InGaN/AlGaN multiple quantum well structure. Additionally, it should be note that light emitted from the active layer 220 of the light emitting device 1 has a wavelength that is affected by the composition and the thickness of the quantum well(s). Furthermore, the thickness of the quantum well structure, the thickness of the barrier(s) and well(s), and the number of alternating layers of barriers and wells may be adjusted to optimize the light emission efficiency of the active layer 220. In this embodiment, the active layer 220 emits light with a wavelength that ranges from 200 nm to 280 nm or from 280 to 360 nm.

Referring to FIG. 1, in some embodiments the semiconductor structure 200 has a plurality of connecting channels. Each of the connecting channels (channel is only in between 230) passes through the second semiconductor layer 230 and the active layer 220 from an upper surface of the second semiconductor layer 230 to an upper surface of the first semiconductor layer 210. The first electrode unit 310 is electrically connected to the first semiconductor layer 210. More specifically the first electrode unit 310 includes a plurality of first contact electrodes 311, a first connecting electrode 312 and a first electrode pad 313. The first contact electrodes 311 are respectively disposed on bottom portions of the connecting channels of the semiconductor structure 200 and each of the first contact electrodes 311 forms an ohmic contact with the first semiconductor layer 210. The first connecting electrode 312 is disposed above the first contact electrodes 311 and electrically connects all of the first contact electrodes 311 disposed in the connecting channels; the electrode pad 313 is disposed on an upper surface of the light emitting device 1. The second electrode unit 320 is electrically connected to the second semiconductor layer 230. The second electrode unit 320 includes a second contact electrode 321 and a second electrode pad 322. The second contact electrode 321 is disposed on top of the semiconductor structure 200. More precisely, the second contact electrode 321 is disposed on the upper surface of the second semiconductor layer 230 and covers the same except the areas where the connecting channels and the first electrode unit 310 are provided. The second contact electrode 321 has two opposite ends, one end forming an ohmic contact with the second semiconductor layer 230 and the other end being electrically connected to the second electrode pad 322 that is located on the upper surface of the light emitting device 1. The first contact electrodes 311 and the second contact electrode 321 are made of a material selected from Cr, Pt, Au, Ni, Ti, and Al, or any combination of the above. The first connecting electrode 312 is made of a material selected from Cr, Al, Ti, Ni, Rh, Pt, and Al, or any combination of the above. However, it should be noted that the materials used for the first contact electrodes 311, the first connecting electrode 312, and the second contact electrode 321 are not limited to the examples given above.

In some embodiments, the light emitting device 1 further includes a current spreading layer 323. The current spreading layer 323 is located between the second contact electrode 321 and the second semiconductor layer 230. The current spreading layer 323 facilitates current spreading and allows more even distribution of current in the light emitting device 1 which improves light emission efficiency. The current spreading layer 323 may be made from a transparent conducting material, or a metal. More specifically, the material used for the current spreading layer 323 may be chosen depending on the dopant used for the second semiconductor layer 230. For example, the second semiconductor layer 230 may be a GaN based P-type semiconductor layer. The transparent conducting material may be indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), tungsten indium oxide or zinc oxide (ZnO). The metal mentioned above may be a nickel gold (Ni/Au) alloy, a nickel rhodium (Ni/Rh) alloy, or a nickel aluminum gold (Ni/Al/Au) alloy, etc. However, the disclosure is not limited to the examples given above. In some embodiments, the current spreading layer 323 may have a thickness that ranges from 500 Å to 1500 Å, and may have a surface plated chromium nickel (Cr/Ni) alloy layer (not shown) covering the current spreading layer 323, thereby forming a light reflecting structure (not shown); or in other embodiments, the current spreading layer 323 may have a thickness that ranges from 100 Å to 500 Å, and may have a surface plated chromium aluminum (Cr/Al) alloy layer (not shown) covering the current spreading layer 323, thereby forming a light absorption structure (not shown).

In the first embodiment of the light emitting device 1 as shown in FIG. 1, the light emitting device 1 further includes an insulating layer 400. The insulating layer 400 may cover the semiconductor structure 200, the first contact electrodes 311, the second contact electrode 312 and the first connecting electrode 312, and electrically insulates these components. The insulating layer 400 includes a first opening 401 and a second opening 402 respectively exposing the first connecting electrode 312 and the second contact electrode 321 for forming electrical connections with the first electrode pad 313 and the second electrode pad 322, respectively. Additionally, portions of the insulating layer 400 are formed on side walls of the active layer 220 and the second semiconductor layer 230 and are located in the connecting channels so that electrical insulation is provided between the first electrode unit 310 and the second electrode unit 320, between individual parts of the active layer 220 and between individual parts of the second semiconductor layer 230. This is a design feature that helps prevent short circuits forming in the light emitting device 1. It should be noted that the insulating layer 400 may provide different functions depending on its location; for example, portions of the insulating layer 400 that cover side walls of the semiconductor structure 200 may help prevent an electrical connection forming between individual parts of the first semiconductor layer 210 and the second semiconductor layer 230, which is a defect that could occur due to overflow of conductive material during the fabrication process, and prevent short circuiting the light emitting device 1. The insulating layer 400 may be an electrical insulating material that includes non-conductive materials, such as inorganic materials or dielectric materials. The inorganic materials may include silicone, and the dielectric materials may include aluminum oxide (AlO), silicon nitride (SiNx), silicon oxide (SiOx), titanium oxide (TiOx), or magnesium fluoride (MgFx). For example, the insulating material 400 may be silicon dioxide (SiO₂), silicon nitride (SiNx), titanium oxide (TiOx), tantalum pentoxide (Ta₂O₅), niobium oxide (NbOₓ), barium titanate (BTO) or any combination of the above. When the insulating material 400 is a combination of some of the examples given above, the insulating material 400 may be structured to form a distributed Bragg reflector with alternating layers selected from two of the materials given above.

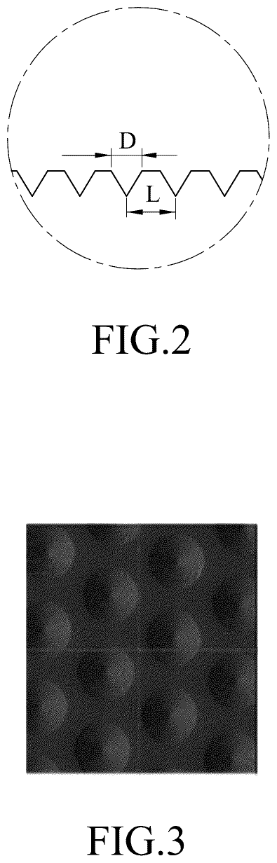

Referring to FIGS. 1 and 3, the plurality of micro elements 110 are located on the second surface 102 of the substrate 100 to increase the light emission efficiency of the light emitting device 1. The micro elements 100 may be formed by a wet etching process, a dry etching process, nanoimprint lithography (NIL), electron-beam lithography, or nanosphere self-assembly etc. The micro elements 110 are arranged periodically or non-periodically, and are cone-shaped, frustocone shaped, cylinder shaped, polygonal pyramid shaped, prism shaped, or spherical. As for the distribution of the micro elements 100, they may be arranged in an array of periodic square grid patterns, an array of periodic hexagonal-close-packing patterns, an array of non-periodic quasicrystalline patterns, or are randomly distributed. In this embodiment, the micro elements 100 are cone-shaped and are arranged in an array of periodic hexagonal-close-packing patterns. However, this is not a limitation of the present disclosure, and in other embodiments the micro elements 110 may be distributed differently. Referring to FIG. 1, in this embodiment, the micro elements 110 include first micro elements 111 that are formed on the second surface 102 of the substrate 100. The first micro elements 111 are extensions of the substrate 100 and are therefore made from a material that is the same as that of the substrate 100. In this embodiment, they are made of a sapphire material. Referring to FIG. 2, each of the micro elements 110 is a protrusion that has a base 12 with a base diameter ranging from 400 nm to 1000 nm. The protrusion may have a shape of a circle or a shape having a circumscribed circle and that has a base diameter (D) ranging from 400 nm to 1000 nm. In some embodiments, the base diameter (D) of the base 12 ranges from 420 nm to 720 nm.

Referring to FIGS. 1 to 3, in the first embodiment, the base diameter (D) ranges from 400 nm to 1000 nm. This specification allows the micro elements 110 to have dimensions that are more compatible with wavelengths in the ultra-violet range, and improves the light extraction efficiency of the light emitting device 1 in the ultra-violet range. More specifically, ultra-violet (UV) light emitted by the active layer 220 will more easily scatter when passing through an interface (i.e., the second surface 102 of the substrate 100) between the substrate 100 and air, thereby minimizing total internal reflection of the UV light at the boundary, and improving the light extraction efficiency of the light emitting device 1. A first experiment was performed using several different sample devices P11, P12, P13, P14, P15, and comparison sample devices P16, P17 and measuring the light intensity of UV light emitted by each sample device. The samples and the comparison samples P11 to P17 emit light with a wavelength ranging from 200 nm to 280 nm, and have an identical structure except the base diameter (D) which is used as a variable. It should be noted that the samples and the comparison samples P11 to P17 all have the light reflecting structure in the current spreading layer 323. Table 1 shows the base diameter (D) of each sample. In the first experiment each sample was connected to the same power source outputting a current of 100 mA with a potential difference of 5.2V. The results of the first experiment show that, according to a descending order of levels of brightness of the samples, the samples may be ordered as follows: P14>P12>P15>P11>P13>P17>P16. The first experiment shows that the size of the base diameter (D) affects the intensity of the UV light emitted by each sample. Therefore, by restricting the base diameter (D) of the base of the micro elements 110 to range from 400 nm to 1000 nm, the light emitting device 1 according to the present disclosure may have an improved light extraction efficiency.

TABLE 1

| sample no. | P11 | P12 | P13 | P14 | P15 | P16 | P17 |
|---|---|---|---|---|---|---|---|
| D(nm) | 701 | 422.9 | 529 | 573.9 | 585 | 254.5 | 166.7 |

Referring to FIG. 2, the base 12 has a base diameter (D) that is 0.8 to 1.5 times, 1.5 to 1.85 times, or 1.85 to 2.5 times the height of a respective one of the micro elements 110. In some embodiments, the base 12 has a base diameter (D) that is 0.8 to 2.5 times the height of the respective one of the micro elements 110. Preferably, the base diameter (D) of the base 12 is 1.5 times to 1.85 times the height of the respective one of the micro elements 110, and a minimum center-to-center (L) distance between every two adjacent ones of the micro elements 110 ranges from 0.5 μm to 1.2 μm.

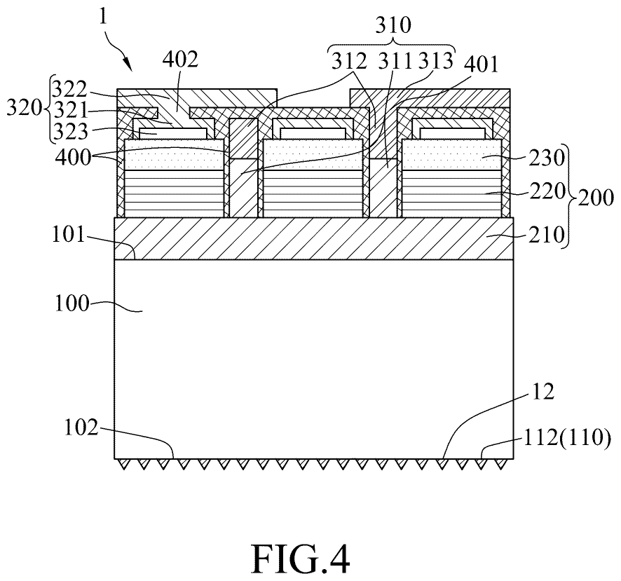

Referring to FIG. 4, a second embodiment of the light emitting device 1 is shown. The second embodiment is similar to the first embodiment and only the differences between the first embodiment and the second embodiment will be discussed in detail below.

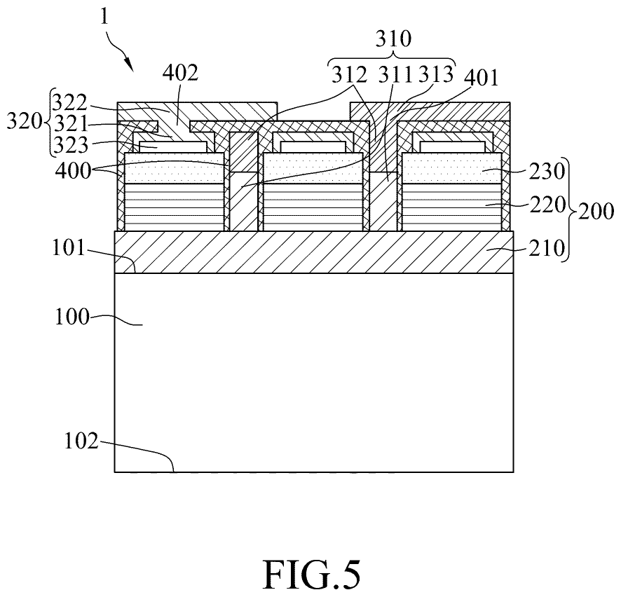

The second embodiment includes a plurality of micro elements 110 located on the second surface 102 of the substrate 100. Referring to FIG. 4, the micro elements 110 include second micro elements 112 that are formed on the second surface 102 of the substrate 100. In the second embodiment, the second micro elements 112 are formed on a smooth second surface 102 as shown in FIG. 5. The substrate 100 includes a first material, and the second micro elements 112 include a second material that is different from the first material. In the second embodiment, the second material has a refraction index that is less than the refraction index of the first material. This helps to minimize the occurrence of large total internal reflection angles which affect light extraction efficiency. More specifically, since UV light has a shorter wavelength, it can produce a relatively large total internal reflection angle when incident on the interface between the substrate and air. This phenomenon can be avoided by providing the second micro elements 112 with the smaller refraction index. The first material is selected from Al2O3, GaN, SiC, and glass, and the second material is selected from SiO2, Si3N4, and ZnO2. In this embodiment the first material is Al₂O₃ with a refraction index of 1.8 and the second material is SiO₂ with a refraction index of 1.47. Each of the second micro elements 112 has a base 12 with a base diameter (D) ranging from 400 nm to 1000 nm. In preferred embodiments, the base diameter (D) of the base 12 of each second micro element 112 ranges from 420 nm to 720 nm.

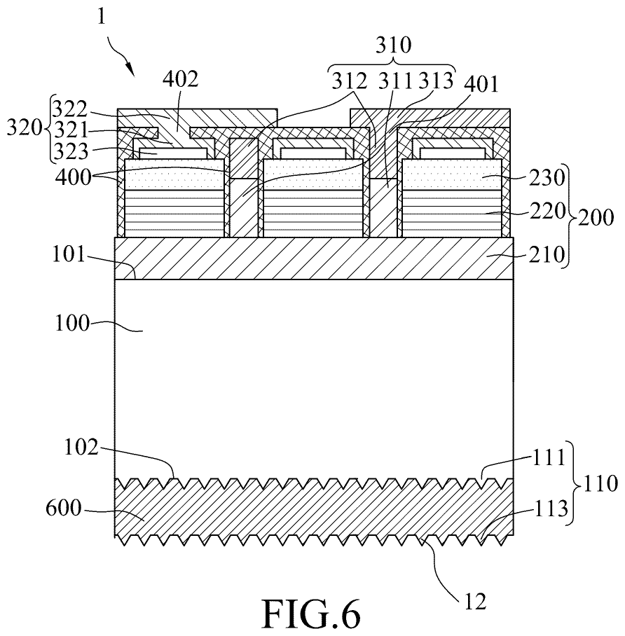

Referring to FIG. 6, a third embodiment of the light emitting device 1 according to the present disclosure is shown. The third embodiment is similar to the first embodiment.

However, the light emitting device 1 of the third embodiment includes a light extraction layer 600 located on a side of the substrate 100 (the second surface 102 of the substrate 100) that is distal to the semiconductor structure 200. In the third embodiment, the light extraction layer 600 covers the first micro elements 111 and the second surface 102 of the substrate 100, the micro elements 110 of the light emitting device 1 include third micro elements 113. In the third embodiment, the light extraction layer 600 is formed via etching or imprint lithography on a light exiting side of the substrate 100, and the third micro elements 113 are formed on a bottom surface of the light extraction layer 600 facing away from the substrate 100. The third micro elements 113 are one piece with the light extraction layer 600. The substrate 100 includes a first material, and the light extraction layer 600 includes a second material that is different from the first material In order to mitigate the reduction in light extraction efficiency due to the light emitting device 1 emitting UV light with a short wavelength, the second material has a refraction index that is less that a refraction index of the first material. The first material is selected from Al₂O₃, GaN, SiC and glass. In this embodiment, the first material is Al₂O₃ with a refraction index of 1.8. The second material is selected from a low refraction index material such as Al₂O₃, SiO₂, Si₃N₄, and ZnO₂. In this embodiment, the second material is SiO₂ with a refraction index of 1.47. The base diameter (D) of the first micro elements 111 and the third micro elements 113 ranges from 400 nm to 1000 nm. In some preferred embodiments, the base diameter (D) the first and third micro elements 111, 113 ranges from 420 nm to 720 nm. The first micro elements 111 and the third micro elements 113 may have the same size, or different sizes. In this embodiment the first micro elements 111 and the third micro elements 113 have the same size.

Referring to FIG. 6, in the third embodiment, by restricting the base diameters (D) of the first micro elements 111 and the third micro elements 113 to be in the range from 400 nm to 1000 nm, the first micro elements 111 and the third micro elements 113 will have a size that is most compatible for improving the light extraction efficiency of light emitted in the UV range. More specifically, light that is emitted from the active layer 220, and that passes through the substrate 100 will more likely scatter when it is incident on an interface (the second surface of the substrate 100) between the substrate 100 and the light extraction layer 600. By virtue of having different refraction indexes for the substrate 100 and the light extraction layer 600, reduction in light extraction efficiency may be mitigated. More specifically, the presence of the light extraction layer 600 reduces the incident of total internal reflection that occurs when the UV light passes the boundary between air and the light extraction layer 600, thereby improving the light extraction efficiency of the light emitting device.

A second experiment was conducted using packaged light emitting devices 1 of the third embodiment. The samples are labelled as P31, P32, P33, P34, and P35, and comparison sample P36, P37. The samples P31 to P37 are tested for intensity and have the same structure, except for the base diameter (D) of the first micro structures 111 and the third micro structure 113, which is used as a variable. In the second experiment each sample was connected to the same power source outputting a current of 100 mA with a potential difference of 5.2V. The samples P31 to P37 emit light with a wavelength ranging from 200 nm to 280 nm, and have the light reflecting structure for the current spreading layer 323. Table 2 lists the base diameters (D) of the first and third micro structures 111, 113 of the samples. Based on the results of the second experiment, the samples and comparison samples are listed in a descending order according to the levels of their emission intensity as follows: P34>P32>P35>P31>P33>P37. The results of the second experiment show that the base diameter (D) of the first and third micro elements 111, 113 is associated with the light emission intensity of the light emitting device 1. Therefore, the first and third micro elements 111, 113 may be designed with a base diameter (D) that is more favorable for increasing the light extraction efficiency of the light emitting device 1.

TABLE 2

| sample | P31 | P32 | P33 | P34 | P35 | P36 | P37 |
|---|---|---|---|---|---|---|---|
| D(nm) | 701 | 422.9 | 529 | 573.9 | 585 | 254.5 | 166.7 |
| Increase of | 7.24% | 2.66% | 6.94% | 6.96% | −6.71% | −5.6% | 1.39% |
| luminous efficacy | | | | | | | |
| (K) | | | | | | | |

The samples and comparison samples P31 to P37 are tested again for light emission intensity under the same parameters, this time the test is conducted before packaging the samples. The test results for light emission intensity before and after packaging are shown in the third row of Table 2 as K, where K=(light emission intensity after packaging/light emission intensity before packaging)−1)×%. The third row of Table 2 shows the values of increases of light intensity K. The results show that the size of the base diameter (D) of the micro elements 110, 130 is not only associated with the light emission efficiency of the light emitting device 1 before packaging but also influences the light emission efficiency after packaging.

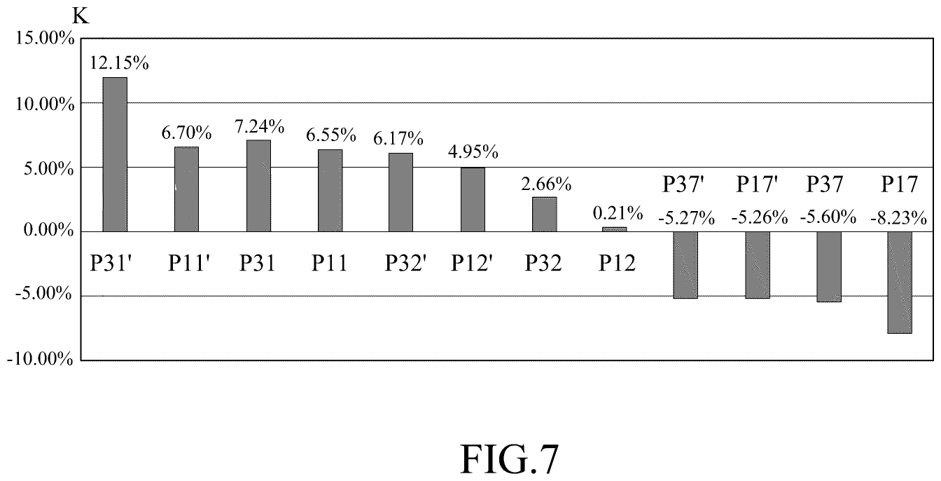

A third experiment is conducted on a first sample group including the samples P11, P31, P12, P32, P17, P37 used in the first and second experiments, and a second sample group including new samples P11′, P31′, P12′, P17′, P37′. The new samples are generally similar to the samples of the first sample group, the only exception being that the current spreading layer 323 of each new sample have the light absorption structure instead of the light reflecting structure of each sample of the first sample group. It should be noted that the light absorption structures in the new samples are identical. The third experiment was conducted using the same current and voltage parameters of the first and second tests, and was conducted to obtain light emission intensity results of the samples both before and after packaging. The results of the third experiment are shown in FIG. 7. The K values of the samples obtained from the third experiment show that the light extraction layer 600 and the third micro elements 113 disclosed in the third embodiment of the light emitting device 1 has a substantial effect on increasing the light emission intensity of packaged light emitting devices 1. Additionally, it can be observed from comparing the results of the new samples with the samples of the first sample group that using the light absorption structure of the current spreading layer 323 has a positive effect on the light emission intensity of packaged light emitting devices 1.

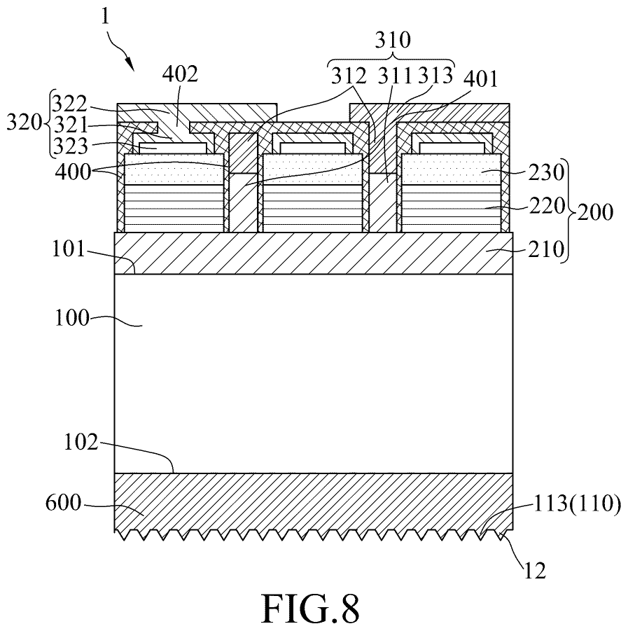

Referring to FIG. 8, a fourth embodiment of the light emitting device according to the present disclosure is shown. The fourth embodiment is similar to the first embodiment so the structural details are omitted; however, the differences between the fourth embodiment and the first embodiment are given below.

The fourth embodiment includes the light extraction layer 600 covering the second surface 102 of the substrate 100. Notably, the second surface 102 of the substrate 100 in the fourth embodiment is smooth as shown in FIG. 5. In the fourth embodiment, the micro elements 110 include third micro elements 113 that are formed on a surface of the light extraction layer 600 facing away from the substrate 100. More specifically, in the fourth embodiment, the third micro elements 113 are formed via etching or imprint lithography on the second surface 102 of the substrate 100; therefore the third micro elements 113 are in one piece with the light extraction layer 600. The substrate 100 includes a first material, the light extraction layer 600 includes a second material that is different from the first material. It should be noted, that since the micro elements 113 are one piece with the light extraction layer 600, the third micro elements 113 include the second material that is different from the first material. The second material has a refraction index that is less than a refraction index of the first material. This helps to minimize occurrence of total internal reflection which improves light extraction efficiency. The first material is selected from Al₂O₃, GaN, SiC or glass, and the second material is selected from Al₂O₃, SiO₂, Si₃N₄, and ZnO₂. In the fourth embodiment, the first material is Al₂O₃ and the second material is ZnO₂ with refractive indices of 1.8 and 1.47, respectively. In the fourth embodiment, the base diameter (D) of the third micro elements 113 ranges from 400 nm to 1000 nm. In some preferred variations of the fourth embodiment, the base diameter (D) ranges from 420 nm to 720 nm.

In some embodiments, the substrate 100 and the light extraction layer 600 are made of materials that have different refractive indices. For example the light emitting device 1 may have a sapphire (Al₂O₃) substrate 100, and a light extraction layer 600 may be made of silicon dioxide (SiO₂). It should be noted that the thickness of the light extraction layer 600 affects the light extraction efficiency of the light emitting device 1 at certain wavelengths. In some embodiments, the active layer 220 emits light with a wavelength that ranges from 265 nm to 285 nm, and the light extraction layer 600 has a thickness that ranges from 400 Å to 600 Å. For example, in an embodiment, for a UV light emitting device that emits UV light with a wavelength of 275 nm, when the light extraction layer 600 has a thickness of 520 Å, a more optimized result of light emission intensity is realized.

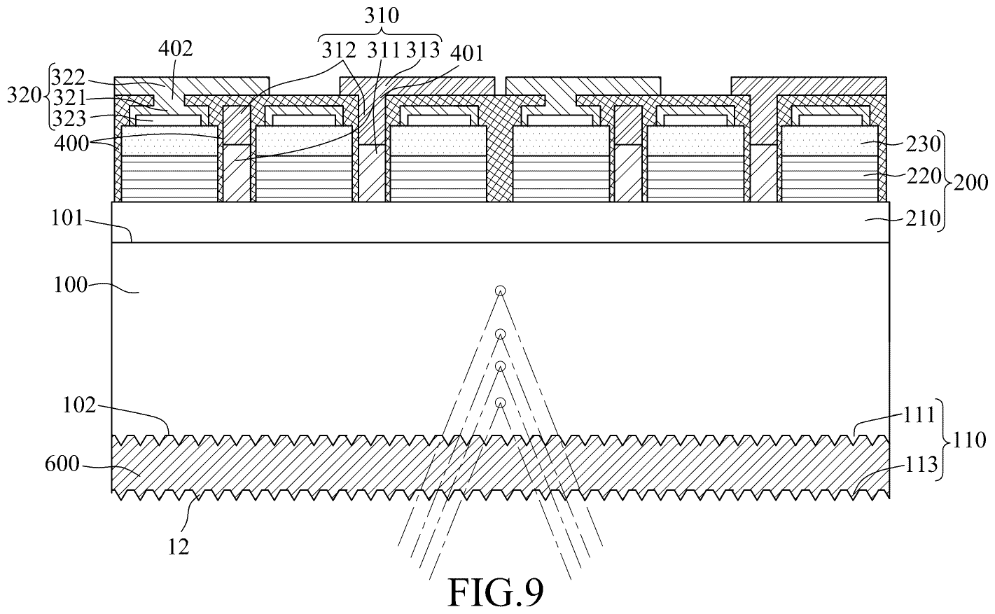

FIG. 9 shows a cross-section view of a pair of light emitting devices 1 before the substrate 100 thereof are stealth diced by a dicing laser. In some embodiments, a stealth dicing process is performed, especially in cases where the substrate 100 is relatively thick, for example on a substrate 100 that has a thickness of 400 nm. During the stealth dicing process, a laser beam is scanned multiple times along dicing lanes of the substrate 100 in order to introduce defect regions within the substrate 100. The dicing laser is usually scanned three to four times in order to inscribe defect regions at different depths along the dicing lanes of the substrate 100. in order to avoid formation of non-uniform laser cuts in a substrate, during laser dicing, due to consumption of energy by a patterned structure on the substrate, especially due to excessive consumption of energy at locations of deep laser cuts, a usual way is to preform pattern-free regions for use as dicing lanes on the substrate so as to assure good dicing quality. However, these measures increase the cost and difficulty of manufacturing the light emitting device 1.

In this embodiment, the substrate 100 is adapted to be stealth diced with a laser that has a wavelength ranging from 900 nm to 1200 nm, and the base diameter (D) of the base 12 of each of the micro elements 110 is smaller than the wavelength of the laser. Referring to FIG. 9, each of the first micro elements 110 and the third micro elements 113 have a base diameter (D) that ranges from 400 nm to 1000 nm. For example, each of the first micro elements 110 and the third micro elements 113 may have a base diameter (D) that is 701 nm. The dicing laser has a wavelength ranging from 900 nm to 1200 nm. For example, the dicing laser may be a pulsed Nd:YAG laser with a wavelength of 1064 nm. Since the base diameters (D) of the bases 12 of the micro elements 110 are smaller than the wavelength of the dicing laser, compared to the UV wavelength of the laser beam of the dicing laser, the second surface of the substrate 100 formed with the relatively small size micro elements 110 nearly resembles an even surface free of micro elements. Therefore, the laser beam can easily refract and enter the inside of the substrate 100 without being affected by the micro elements 110, and the energy loss thereof is low. This design has the advantage of not needing to preform pattern-free dicing lanes and helps to reduce cost and facilitate fabrication of the light emitting device 1. In some embodiments, the base diameter (D) of the base 12 of each of the micro elements 110 is smaller than 0.75 times the wavelength of the laser. This specification facilitates the stealth dicing processes. By limiting the size of the micro elements 110 so that they do not adversely affect the effectiveness of the laser; particularly the micro elements 110 may alleviate the problem laser energy losses due to the scattering of laser beam by the conventional micro elements.

A light emitting assembly using the light emitting device 1 is also herein disclosed.

In summary of the above, in the light emitting device 1 according to the present disclosure, by virtue of adjusting the size of the base diameters (D) of the bases 12 of the micro elements 110 to be compatible with the wavelength of UV light emitted by the light emitting device 1, the light extraction efficiency of the light emitting device 1 may be improved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light emitting device comprising:
a substrate having a first surface and a second surface opposite to said first surface;
a semiconductor structure located on top of said first surface of said substrate, and having a first semiconductor layer, an active layer, and a second semiconductor layer that are stacked sequentially;
a first electrode unit electrically connected to said first semiconductor layer; a second electrode unit electrically connected to said second semiconductor layer; and
a plurality of micro elements located on said second surface of said substrate, each of said micro elements being a protrusion that has a base with a base diameter ranging from 400 nm to 1000 nm.

2. The light emitting device as claimed in claim 1, wherein said active layer emits light with a wavelength that ranges from 200 nm to 280 nm or from 280 nm to 360 nm.

3. The light emitting device as claimed in claim 1, wherein:
said micro elements include first micro elements that are formed on said second surface of said substrate; and
said first micro elements of said micro elements are made of a material that is the same as that of said substrate.

4. The light emitting device as claimed in claim 1, wherein said micro elements include second micro elements that are formed on said second surface of said substrate, said substrate including a first material, said second micro elements including a second material that is different from said first material.

5. The light emitting device as claimed in claim 3, further comprising a light extraction layer covering said first micro elements and said second surface of said substrate, wherein:
said micro elements further include a plurality of third micro elements that are formed on a bottom surface of said light extraction layer facing away from said substrate;
said substrate including a first material, said light extraction layer including a second material that is different from said first material; and
said third micro elements include said second material that is different from said first material.

6. The light emitting device as claimed in claim 1, further comprising a light extraction layer covering said second surface of said substrate, wherein:
said micro elements include third micro elements that are formed on a surface of said light extraction layer facing away from said substrate;
said substrate including a first material, said light extraction layer including a second material that is different from said first material; and
said third micro elements include said second material that is different from said first material.

7. The light emitting device as claimed in claim 5, wherein:
said active layer emits light with a wavelength that ranges from 265 nm to 285 nm; and
said light extraction layer has a thickness that ranges from 400 Å to 600 Å.

8. The light emitting device as claimed in claim 6, wherein:
said active layer emits light with a wavelength that ranges from 265 nm to 285 nm; and
said light extraction layer has a thickness that ranges from 400 Å to 600 Å.

9. The light emitting device as claimed in claim 4, wherein said second material has a refraction index that is less than a refraction index of said first material.

10. The light emitting device as claimed in claim 6, wherein said second material has a refraction index that is less than a refraction index of said first material.

11. The light emitting device as claimed in claim 8, wherein:
said first material is selected from Al₂O₃, GaN, SiC, and glass, and said second material is selected from Al₂O₃, SiO₂, Si₃N₄, and ZnO₂.

12. The light emitting device as claimed in claim 1, wherein said base diameter of said base ranges from 420 nm to 720 nm.

13. The light emitting device as claimed in claim 1, wherein said base has said base diameter that is 0.8 to 1.5 times, 1.5 to 1.85 times, or 1.85 to 2.5 times the height of a respective one of said micro elements.

14. The light emitting device as claimed in claim 1, wherein a minimum center-to-center distance between every two adjacent ones of said micro elements ranges from 0.5 μm to 1.2 μm.

15. The light emitting device as claimed in claim 1, wherein said micro elements are cone shaped, frustocone shaped, cylinder shaped, polygonal pyramid shaped, prism shaped, or spherical.

16. The light emitting device as claimed in claim 1, wherein said micro elements are arranged in an array of periodic square grid patterns, an array of periodic hexagonal-close-packing patterns, an array of non-periodic quasicrystalline patterns, or are randomly distributed.

17. The light emitting device as claimed in claim 1, wherein:
light generated in said active layer of said semiconductor structure is emitted along a direction towards said substrate; and
said first electrode unit and said second electrode unit are located on a side of said semiconductor structure distal to said second surface of said substrate.

18. The light emitting device as claimed in claim 1, wherein:
said substrate is adapted to be stealth diced with a laser that has a wavelength ranging from 900 nm to 1200 nm; and
said base diameter of said base of each of said micro elements is smaller than the wavelength of the laser.

19. The light emitting device as claimed in claim 18, wherein
said base diameter of said base of each of said micro elements is smaller than 0.75 times the wavelength of the laser.

20. A light emitting assembly using the light emitting device in claim 1.
